(19) United States
(12) Patent Application Publication
(10) Pub. No.: US 2026/0136867 A1
(43) Pub. Date: May 14, 2026

(54) SUBSTRATE TREATING APPARATUS AND SUBSTRATE TREATING METHOD USING THE SAME

(71) Applicant: SEMES CO., LTD., Cheonan-si, Chungcheongnam-do (KR)

(72) Inventors: In Ki JUNG, Seongnam-si (KR); Jun Ho SONG, Hwaseong-si (KR); Jeong Bo SHIM, Suwon-si (KR); Won Sik SON, Hwaseong-si (KR); Jeong Hyup YU, Hwaseong-si (KR)

(73) Assignee: SEMES CO., LTD., Cheonan-si, Chungcheongnam-do (KR)

(21) Appl. No.: 19/389,411

(22) Filed: Nov. 14, 2025

(30) Foreign Application Priority Data
Nov. 14, 2024 (KR) 10-2024-0162127

(51) Int. Cl. H01L 21/67

(52) U.S. Cl. CPC H10P 72/0404

(57) ABSTRACT

The present invention relates to a substrate treating apparatus and a substrate treating method using the same, and a first driving unit, which is a structure that allows a chuck pin and a guide ring unit to move at the same time, includes a bearing, thereby reducing damage to a puddle and ensuring substrate treatment uniformity by rotating the substrater even when a guide ring is lowered and the chuck pin is separated from the substrate.

### CROSS-REFERENCE TO RELATED APPLICATION

This application claims priority to and the benefit of Korean Patent Application No. 10-2024-0162127 filed in the Korean Intellectual Property Office on Nov. 14, 2024, the entire contents of which are incorporated herein by reference.

### TECHNICAL FIELD

The present invention relates to a substrate treating apparatus and a substrate treating method using the same, and more particularly, to an apparatus for liquid-treating a substrate, and a method of treating a substrate by using the apparatus.

### BACKGROUND ART

A semiconductor process includes a process of cleaning thin films, foreign substances, particles, and the like on a substrate. The cleaning process is performed by placing a substrate on a spin chuck and supplying a treatment liquid to an upper surface of the substrate while rotating a support unit.

The support unit may rotate at various speeds depending on the supplied treatment liquid, and the treatment liquid includes various types of chemical solutions, such as a rinse liquid, a dry liquid, and an etching liquid. When a rinse liquid and a dry liquid are supplied, the support unit may rotate at high speed, and in this process, some of the treatment liquid is scattered from the substrate by centrifugal force. In general, the scattered treatment liquid may cause generation of particles and is recovered as a treating bowl. However, since the treating bowl is separated from the substrate by a certain distance, as the rotation speed of the spin chuck increases, the amount and range of the treatment liquid scattered increase, resulting in a problem that is difficult to recover. To solve this problem, a guide ring was introduced to guide the treatment liquid to the treating bowl at a position closer to the substrate than the treating bowl.

However, when a guide ring is applied, a puddle is formed with an etchant and a bridge phenomenon occurs between the puddle and the guide ring in the process of treating the substrate, making it difficult to keep the puddle stable. In addition, when the guide ring is introduced, a technology that can elevate and lower the guide ring was applied to avoid interference with the robot transferring the substrate, but this technology had a limitation in that the substrate could not be rotated in a state where the guide ring was lowered. This is because the driven handle connected to the guide ring is designed to descend together when the driving handle applies downward force. As a result, the treatment liquid could be effectively recovered through the guide ring, but in the process of treating the substrate by forming the puddle, it was difficult to rotate the support unit, and it was difficult to keep the puddle stable.

### SUMMARY OF THE INVENTION

The present invention has been made in an effort to provide a substrate treating apparatus capable of improving the uniformity of liquid treatment of a substrate and a substrate treating method using the same.

The present invention has also been made in an effort to provide a substrate treating apparatus capable of minimizing damage to a puddle and a substrate treating method using the same.

The present invention has been made in an effort to provide a substrate treating apparatus capable of rotating a substrate even when a guide ring is lowered and a substrate treating method using the same.

The present invention has been made in an effort to provide a substrate treating apparatus capable of rotating a substrate even when a chuck pin is spaced apart from the substrate and a substrate treating method using the same.

The objectives of the present disclosure are not limited thereto and other objectives not stated herein may be clearly understood by those skilled in the art from the following description.

An exemplary embodiment of the present disclosure, an apparatus for treating a substrate, the apparatus comprising: a treating bowl configured to a treatment space for treating a substrate; a support unit configured to support and rotate the substrate in the treatment space; and a treatment liquid supply unit configured to supply a treatment liquid to an upper surface of the substrate supported by the support unit, wherein the support unit includes: a spin chuck on which the substrate is placed and rotates; a chuck pin installed on the spin chuck to support a side portion of the substrate placed on the spin chuck; a chuck pin support configured to support the chuck pin; a guide ring unit provided between the treating bowl and the spin chuck and having a shape surrounding the spin chuck in a circumferential direction of the spin chuck; and a driving assembly configured to move the guide ring unit so that the guide ring unit is moved between a raised position and a lowered position, the raised position is a position where the guide ring unit ascends to guide a treatment liquid scattered from the substrate supported by the support unit to the treating bowl, the lowered position is the position where the guide ring unit is lowered below the support unit, when the guide ring unit moves to the raised position, the chuck pin is moved to a support position to support the substrate by gripping the side portion of the substrate supported by the spin chuck, and when the guide ring unit moves to the lowered position, the chuck pin is moved to a separation position, which is a position spaced apart from the substrate supported by the spin chuck, and the driving assembly may be provided to rotate the spin chuck in a state where the guide ring unit is moved to the lowered position.

According to the exemplary embodiment of the present invention, wherein the driving assembly includes: a first driving unit to which the guide ring unit is coupled; and a second driving unit configured to move the first driving unit in a vertical direction, the first driving unit includes a bearing, and the second driving unit may includes a handle provided to be in contact with the bearing.

According to the exemplary embodiment of the present invention, wherein the bearing includes: an outer ring and an inner ring; and a roller provided between the outer ring and the inner ring, and the handle may be provided to be in contact with the outer ring.

According to the exemplary embodiment of the present invention, wherein an upper surface of the outer ring is provided as a horizontal plane, the handle is provided to at least partially overlap the outer ring when viewed from above, and a bottom surface of the handle may be provided to be in contact with the horizontal surface.

According to the exemplary embodiment of the present invention, wherein the outer ring may be provided to be fixed against a rotation of the inner ring when the inner ring rotates in a state where the handle is in contact with the outer ring.

According to the exemplary embodiment of the present invention, wherein the bearing may be a cross roller bearing.

According to the exemplary embodiment of the present invention, wherein the chuck pin support includes a protrusion that has a longitudinal direction in a radial direction of the spin chuck and extends downward from the chuck pin support, the first driving unit further includes a connector connecting the guide ring unit and the bearing, the connector has a pusher at a position partially overlapping the protrusion when viewed from above, when the guide ring unit is moved to the raised position, the pusher pushes the protrusion to move the chuck pin to the support position, and when the guide ring unit is moved to the lowered position, the chuck pin may be moved to the separation position.

According to the exemplary embodiment of the present invention, wherein the separation position may be a position where the treatment liquid supplied onto the substrate supported by the chuck pin does not contact the chuck pin.

According to the exemplary embodiment of the present invention, wherein the guide ring unit includes: a guide ring that is provided in a ring shape and has a groove at a position corresponding to the chuck pin; and a support body configured to support the guide ring, the guide ring is provided to be adjacent to the substrate supported by the chuck pin at the raised position, and the chuck pin is located in the groove, and the groove may has a width that does not interfere with the guide ring when the chuck pin is moved between the separation position and the support position.

An exemplary embodiment of the present disclosure, a method of treating a substrate by using the apparatus for treating the substrate of claim 1, the method comprising: a second rotating operation of treating the substrate with the treatment liquid supplied onto the substrate while rotating the spin chuck at a second speed in an open state, wherein the open state may be a state where the substrate is placed on the spin chuck, the chuck pin is moved to a separation position, and the guide ring unit is moved to a lowered position.

According to the exemplary embodiment of the present invention, a loading operation of loading the substrate onto the spin chuck in the open state; a gripping operation of switching from the open state to a closed state; and a first rotating operation of supplying the treatment liquid onto the substrate in the closed state and rotating the spin chuck at a first speed, wherein the second rotating operation may be performed after the first rotating operation.

According to the exemplary embodiment of the present invention, wherein the second speed may be lower than the first speed.

According to the exemplary embodiment of the present invention, wherein the second speed may be 10 RPM or less.

According to the exemplary embodiment of the present invention, wherein the treatment liquid is a first treatment liquid, the treatment liquid supply unit is provided to supply the first treatment liquid and a second treatment liquid, the method further comprises: after the second rotating operation, a rinsing operation of gripping, by the chuck pin, the substrate, supplying the second treatment liquid, and rotating the substrate at a third speed; and a drying operation of rotating the substrate at a fourth speed, and the third speed and the fourth speed may be faster than the first speed.

An exemplary embodiment of the present disclosure, an apparatus for treating a substrate, the apparatus comprising: a treating bowl configured to a treatment space for treating a substrate; a support unit configured to support and rotate the substrate in the treatment space; and a treatment liquid supply unit configured to supply a treatment liquid to an upper surface of the substrate supported by the support unit, wherein the support unit includes: a spin chuck on which the substrate is placed and rotates; a chuck pin installed on the spin chuck to support a side portion of the substrate placed on the spin chuck; a guide ring unit provided between the treating bowl and the spin chuck and having a shape surrounding the spin chuck in a circumferential direction of the spin chuck; and a driving assembly configured to move the guide ring so that the guide ring unit is moved between a raised position and a lowered position, the raised position is a position where the guide ring unit ascends to guide a treatment liquid scattered from the substrate supported by the support unit to the treating bowl, the lowered position is the position where the guide ring unit is lowered below the support unit, when the guide ring unit moves to the raised position, the chuck pin is moved to a support position to support the substrate by gripping the side portion of the substrate supported by the spin chuck, and when the guide ring unit moves to the lowered position, the chuck pin is moved to a separation position, which is a position spaced apart from the substrate supported by the spin chuck, and the driving assembly includes: a first driving unit to which the guide ring unit is coupled; and a second driving unit configured to move the first driving unit in a vertical direction, the first driving unit includes a bearing, and the second driving unit includes a handle provided to be in contact with the bearing, the driving assembly is provided to rotate the spin chuck in a state where the guide ring unit is moved to the lowered position, the bearing includes: an outer ring and an inner ring; and a roller provided between the outer ring and the inner ring, and the handle may be provided to be in contact with the outer ring, and the outer ring is provided to be fixed against a rotation of the inner ring when the inner ring rotates in a state where the handle is in contact with the outer ring.

According to the exemplary embodiment of the present invention, wherein the separation position may be a position where the treatment liquid supplied onto the substrate supported by the chuck pin does not contact the chuck pin.

According to the exemplary embodiment of the present invention, wherein the guide ring unit includes: a guide ring that is provided in a ring shape and has a groove at a position corresponding to the chuck pin; and a support body configured to support the guide ring, the guide ring is provided to be adjacent to the substrate supported by the chuck pin at the raised position, and the chuck pin is located in the groove, and the groove may has a width that does not interfere with the guide ring when the chuck pin is moved between the separation position and the support position.

According to the exemplary embodiment of the present invention, wherein the support unit includes a chuck pin support to support the chuck pin, the chuck pin support includes a protrusion that has a longitudinal direction in a radial direction of the spin chuck and extends downward from the chuck pin support, the chuck pin is installed on the chuck pin support, the first driving unit further includes a connector connecting the guide ring unit and the bearing, the connector has a pusher at a position partially overlapping the protrusion when viewed from above, when the guide ring unit is moved to the raised position, the pusher pushes the protrusion to move the chuck pin to the support position, and when the guiding unit is moved to the lowered position, the chuck pin may be moved to the separation position.

According to the exemplary embodiment of the present invention, a controller, the controller controls to perform a second rotating operation of rotating the spin chuck at a second speed in an open state, and the open state is a state where the substrate is placed on the spin chuck, the chuck pin is moved to a separation position, and the guide ring unit may be moved to a lowered position.

According to the exemplary embodiment of the present invention, wherein the controller controls to perform the second rotating operation after: a loading operation of loading the substrate onto the spin chuck in the open state; a gripping operation of switching from the open state to a closed state; and a first rotating operation of supplying the treatment liquid onto the substrate in the closed state and rotating the spin chuck at a first speed, and the second speed may be lower than the first speed.

According to the exemplary embodiment of the present invention, it is possible to improve the uniformity of liquid treatment of a substrate.

According to the exemplary embodiment of the present invention, it is possible to minimize damage to a puddle.

According to the exemplary embodiment of the present invention, it is possible to rotate a substrate even when a guide ring is lowered.

According to the exemplary embodiment of the present invention, it is possible to rotate a substrate even when a chuck pin is spaced apart from the substrate.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a top plan view schematically illustrating a substrate treating apparatus according to an exemplary embodiment of the present invention.

FIG. 2 is a diagram schematically illustrating an exemplary embodiment of a liquid treating chamber of FIG. 1.

FIG. 3 is a diagram schematically illustrating an exhaust path and a drainage path of the liquid treating chamber of FIG. 2.

FIG. 4 is a diagram schematically illustrating an exemplary embodiment of a support unit of FIG. 2.

FIG. 5 is a diagram illustrating a state in which a chuck pin is positioned at a separation position and a guide ring unit is positioned at a lowered position.

FIG. 6 is a diagram illustrating a state in which the chuck pin moves from the separation position to a support position and the guide ring unit moves from the lowered position to a raised position.

FIG. 7 is a diagram illustrating a bearing of FIG. 4 in detail.

FIG. 8 is a flowchart illustrating a substrate treating method according to an exemplary embodiment of the present invention.

FIG. 9 is a diagram illustrating a state in which a treatment liquid is supplied onto a substrate in a first rotating operation.

FIG. 10 is a diagram illustrating a state in which a puddle is formed on a substrate in a second rotating operation.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer is described as an example as an object to be treated. However, the technical idea of the present invention may be applied to devices used for treating other types of substrates other than wafers as objects to be treated.

Hereinafter, an exemplary embodiment of the present invention will be described with reference to the accompanying drawings.

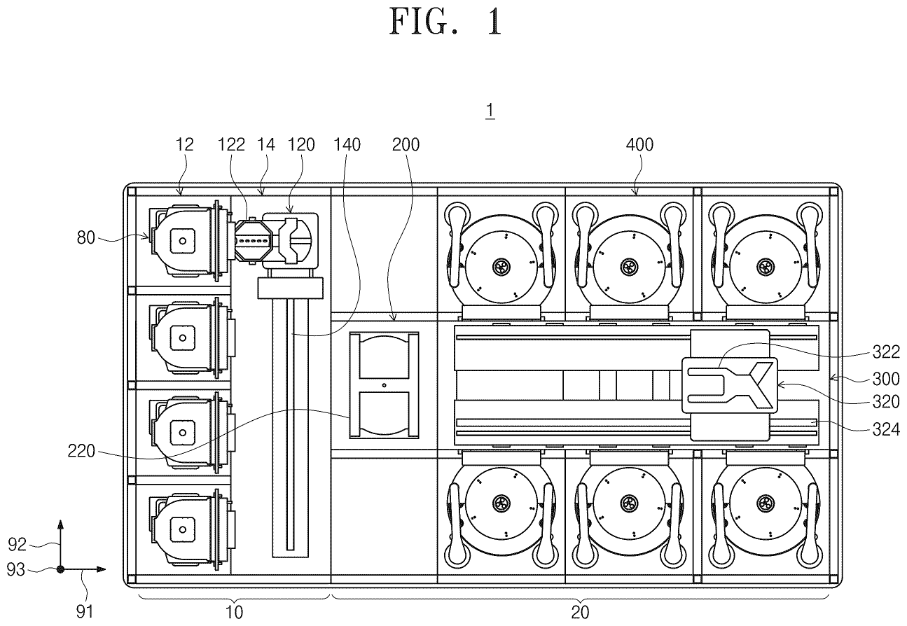

FIG. 1 is a top plan view schematically illustrating a substrate treating apparatus according to an exemplary embodiment of the present invention. Referring to FIG. 1, a substrate treating apparatus includes an index module 10, a treating module 20, and a controller 30. According to the exemplary embodiment, the index module 10 and the treating module 20 are disposed along one direction. Hereinafter, the direction in which the index module 10 and the treating module 20 are disposed is referred to as a first direction 91, and when viewed from above, a direction perpendicular to the first direction 91 is referred to as a second direction 92, and a direction perpendicular to both the first direction 91 and the second direction 92 is referred to as a third direction 93.

The index module 10 transfers a substrate W from a container 80 in which the substrate W is accommodated to the treating module 20, and makes the substrate W, which has been completely treated in the treating module 20, be accommodated in the container 80. A longitudinal direction of the index module 10 is provided in the second direction 92. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plurality, and the plurality of load ports 12 may be disposed in the second direction 92.

As the container 80, an airtight container, such as a Front Open Unified Pod (FOUP), may be used. The container 80 may be placed on the load port 12 by a transfer means (not illustrated), such as an overhead transfer, an overhead conveyor, or an automatic guided vehicle, or an operator.

An index robot 120 is provided to the index frame 14. A guide rail 140 of which a longitudinal direction is the second direction 92 is provided within the index frame 14, and the index robot 120 may be provided to be movable on the guide rail 140. The index robot 120 includes a hand 122 on which the substrate W is placed, and the hand 122 may be provided to be movable forward and backward, rotatable about the third direction 93, and movable along the third direction 93. The plurality of hands 122 is provided while being spaced apart from each other in the up and down direction, and is capable of independently moving forward and backward.

The treating module 20 includes a buffer unit 200, a transfer chamber 300, and a liquid treating chamber 400. The buffer unit 200 provides a space in which the substrate W loaded into the treating module 20 and the substrate W unloaded from the treating module 20 stay temporarily. The liquid treating chamber 400 performs a process of liquid-treating the substrate W by supplying a treatment liquid onto the substrate W. The transfer chamber 300 transfers the substrate W between the buffer unit 200 and the liquid treating chamber 400.

The transfer chamber 300 may be provided so that a longitudinal direction is the first direction 91. The buffer unit 200 may be disposed between the index module 10 and the transfer chamber 300. A plurality of liquid treating chambers 400 is provided and may be disposed on the side of the transfer chamber 300. The liquid treating chamber 400 and the transfer chamber 300 may be disposed in the second direction 92. The buffer unit 200 may be located at one end of the transfer chamber 300.

According to the example, the liquid treating chambers 400 are respectively disposed on opposite sides of the transfer chamber 300. At each of opposite sides of the transfer chamber 300, the liquid treating chambers 400 may be provided in an array of A×B (each of A and B is 1 or a natural number greater than 1) in the first direction 91 and the third direction 93.

The transfer chamber 300 includes a transfer robot 320. A guide rail 340 having a longitudinal direction in the first direction 91 is provided in the transfer chamber 300, and the transfer robot 320 may be provided to be movable on the guide rail 340. The transfer robot 320 includes a hand 322 in which the substrate W is placed, and the hand 322 may be provided to be movable forwardly and backwardly, rotatable about the third direction 93, and movable along the third direction 93. A plurality of hands 322 are provided to be spaced apart in the vertical direction, and the hands 322 may move forward and backward independently of each other.

The buffer unit 200 includes a plurality of buffers 220 on which the substrate W is placed. The buffers 220 may be disposed while being spaced apart from each other in the third direction 93. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

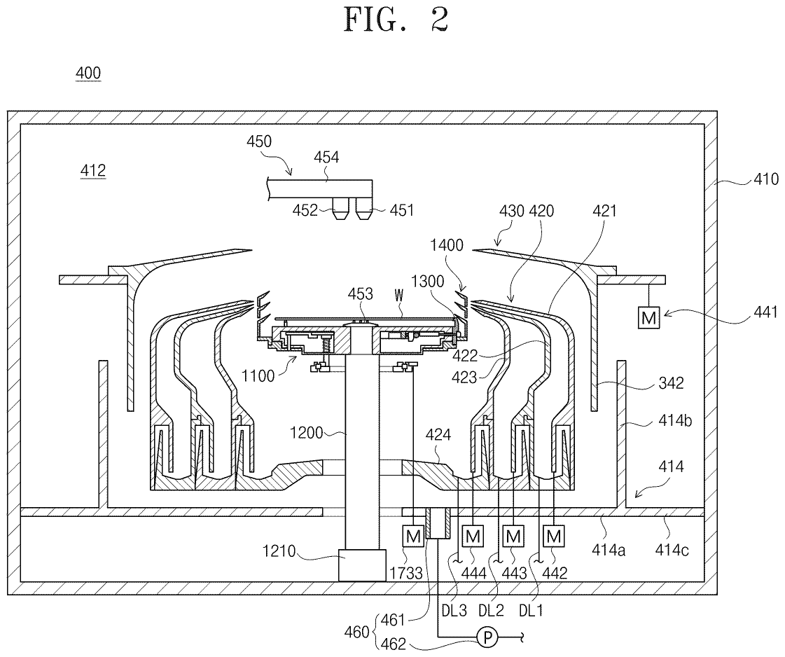

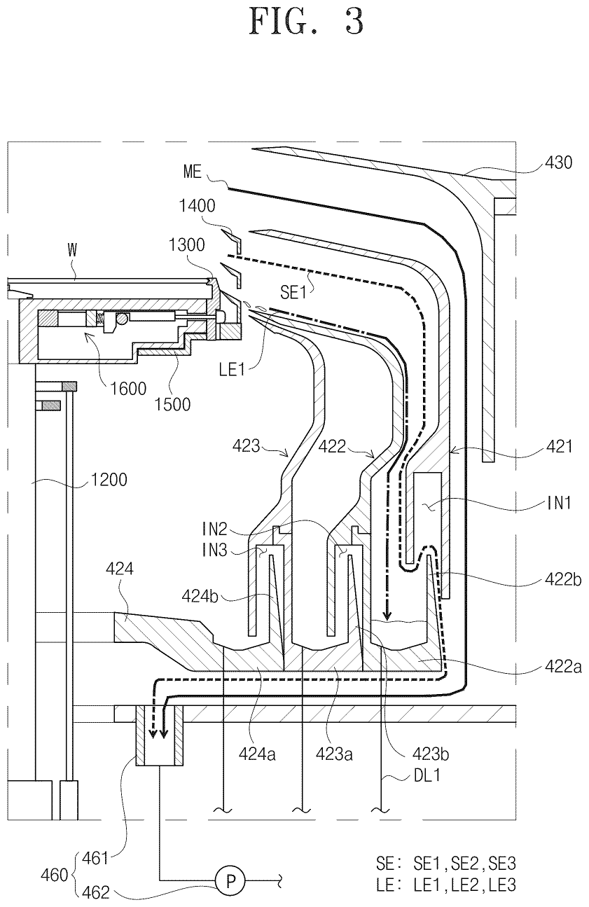

FIG. 2 is a diagram schematically illustrating an exemplary embodiment of the liquid treating chamber of FIG. 1, and FIG. 3 is a diagram schematically illustrating an exhaust path and a drainage path of the liquid treating chamber of FIG. 2. Referring to FIGS. 2 and 3, the liquid treating chamber 400 includes a housing 410, a treating bowl 420, an exhaust bowl 430, a plurality of lifting mechanisms 441, 442, 443, and 444, a liquid supply unit 450, an exhaust unit 460, a support unit 1000, and a controller 900.

The housing 410 is provided in a generally rectangular parallelepiped shape. The housing provides an inner space 412. The configurations to be described below may be disposed inside the housing 410. An opening (not illustrated) provided as a passage of the substrate W may be formed in the side portion of the housing 410. An exhaust path forming member 414 may be provided in the inner space 412 provided by the housing 410.

The exhaust path forming member 414 may include a first part 414a extending in the horizontal direction from the lower side of the treating bowl 420 to be described later, a second part 414b extending in the vertical direction from the outside of the exhaust bowl 430, and a third part 414c extending in the horizontal direction from the outside of the second part 414b.

When viewed from the top, the exhaust path forming member 414 may have a plate shape in which a circular hole is formed in a central region. The exhaust path forming member 414 may be combined with the treating bowl 420 to define a main exhaust path ME and a sub exhaust path SE. Also, unlike the treating bowl 420 and the exhaust bowl 430, the height of the exhaust path forming member 414 may be fixed and provided. Also, a rotation shaft 1200 of a spin chuck 1100, which will be described later, may be inserted into and provided in a hole formed in a central region of the exhaust path forming member 414.

The treating bowl 420 may recover the treatment liquid supplied by the liquid supply unit 450. The treating bowl 420 may exhaust the airflow around the substrate W. The treating bowl 420 may provide a liquid recovery path and an airflow exhaust path. The treatment liquid supplied by the liquid supply unit 450 may be recovered through the liquid recovery path, and the airflow around the substrate W may be exhausted to the outside of the liquid treating chamber 400 through the airflow exhaust path.

The treating bowl 420 may include a first bowl 421, a second bowl 422, a third bowl 423, and a liquid receiving member 424. The first bowl 421, the second bowl 422, the third bowl 423, and the liquid receiving member 424 may have a ring shape surrounding the periphery of the spin chuck 1100. Also, the first bowl 421, the second bowl 422, and the third bowl 423 may be provided in a structure in which upper portions thereof are stacked on each other.

The first bowl 421 may be an outer bowl. The first bowl 421 may be a bowl disposed at the outermost side among the plurality of bowls included in the treating bowl 420. The first bowl 421 may be provided in a shape in which upper and lower portions are open. A first groove IN1 may be formed at a lower end of the first bowl 421 toward the first bowl 421. An outer wall 422b of a first liquid receiving part 422a formed an outer side of a lower end of the second bowl 422 may be inserted into the first groove IN1.

The second bowl 422 may be an intermediate bowl. The second bowl 422 may be a bowl placed between the outermost bowl and the innermost bowl among the plurality of bowls included in the treating bowl 420. The first bowl 422 may be provided in a shape in which upper and lower portions are open. A second groove IN2 may be formed at the lower end of the second bowl 422 toward the inner side of the second bowl 422. An outer wall 423b of a second liquid receiving part 423a formed at an outer side of the lower end of the third bowl 423 may be inserted into the second groove IN2.

The third bowl 423 may be an inner bowl. The third bowl 423 may be a bowl disposed at the innermost side among the plurality of bowls included in the treating bowl 420. The third bowl 423 may be provided in a shape in which upper and lower portions are open. A third groove IN3 may be formed at a lower end of the third bowl 423 toward the third bowl 423. An outer wall 424b of a third liquid receiving part 424a formed at an outer side of the liquid receiving member 424 may be inserted into the third groove IN3.

The liquid receiving member 424 may be provided inside the third bowl 423. The liquid receiving member 424 may be provided at the same height as the first liquid receiving part 421a and the second liquid receiving part 422a. The third liquid receiving part 424a may be formed at the outer side of the liquid receiving member 424.

A first drain line DL1 may be connected to the second bowl 422, a second drain line DL2 may be connected to the third bowl 423, and a third drain line DL3 may be connected to the liquid receiving member 424. Each of the first to third drain lines DL1, DL2, and DL3 may drain the treatment liquid recovered through the liquid receiving part to the outside of the substrate treating apparatus 400. The first to third drain lines DL1, DL2, and DL3 may also recover different types of treatment liquid or, in some cases, may recover the same type of treatment liquid.

Also, the first bowl 421, the second bowl 422, and the third bowl 423 may be configured to be lifted. The first bowl 421, the second bowl 422, and the third bowl 423 may be configured to be lifted by the second lifting mechanism 442, the third lifting mechanism 443, and the fourth lifting mechanism 444, respectively. The second lifting mechanism 442, the third lifting mechanism 443, and the fourth lifting mechanism 444 may be mechanisms capable of generating lifting driving force capable of lifting the first bowl 421, the second bowl 422, and the third bowl 423, such as a motor or pneumatic/hydraulic cylinder. As the first bowl 421, the second bowl 422, and the third bowl 423 are selectively lifted, a plurality of sub-exhaust paths SE and a plurality of liquid recovery paths LE may be formed. For example, when the first bowl 421 ascends, a first sub-exhaust path SE1 and a first liquid recovery path LE1 are formed, when the first bowl 421 and the second bowl 422 ascend, a second sub-exhaust path SE2 and a second liquid recovery path LE2 are formed, and when the first bowl 421, the second bowl 422, and the third bowl 423 ascend, a third sub-exhaust path SE3 and a third liquid recovery path LE3 may be formed.

The exhaust bowl 430 may be installed to be spaced apart from the outside of the treating bowl 420. The exhaust bowl 430 may be disposed to be spaced apart from the outer bowl 421, which is the outermost bowl among the plurality of bowls of the treating bowl 420. The exhaust bowl 430 may be disposed to be spaced apart from the outer bowl 421 to define at least a portion of the main exhaust path ME that exhausts the airflow around the substrate W placed on the spin chuck 1100. The exhaust bowl 430 may be configured to be lifted by the first lifting mechanism 441. The first lifting mechanism 441 may include a lifting motor. However, the present invention is not limited thereto, and the first lifting mechanism 441 may use a pneumatic cylinder or a hydraulic cylinder as a configuration for generating lifting driving force.

The liquid supply unit 450 supplies a treatment liquid to a substrate supported by the support unit 1000. The liquid supply unit 450 includes a first nozzle 1420a, a second nozzle 1420b, and a back nozzle 453. The first nozzle 451 supplies a first treatment liquid to the upper surface of the substrate W supported by the chuck pin 1300. The first nozzle 452 supplies a first treatment liquid to the upper surface of the substrate W supported by the chuck pin 1300. The first nozzle 451 and the second nozzle 452 are supported by a nozzle support 454. Selectively, the first nozzle support 454 moves the first nozzle 451 and the second nozzle 452 between a raised position and a lowered position. In the raised position, the first nozzle 451 and the second nozzle 452 each supply a first treatment liquid or a second treatment liquid to the substrate W placed on the spin chuck 1100, and the first nozzle 451 and the second nozzle 452 which have completed supplying the first treatment liquid or the second treatment liquid wait in the lowered position. According to an exemplary embodiment, the first treatment liquid may be chemical, and the second treatment liquid may be deionized water. Optionally, the liquid supply unit 450 may further include an additional nozzle. The additional nozzle may be provided to be supported by the nozzle support 454, or may be provided to be supported by an independent support. Furthermore, the additional nozzle may be provided to supply a treatment liquid of a type different from that of the first treatment liquid, the second treatment liquid, and the third treatment liquid.

The back nozzle 453 is installed on an upper surface of the spin chuck 1100 to be described later. Also, a through hole 1100a for installing the back nozzle 453 may be formed in the center of the spin chuck 1100. The back nozzle 453 supplies the third treatment liquid to a bottom surface of the substrate W supported by the chuck pin 1300. According to an exemplary embodiment, the third treatment liquid may be ultrapure water.

The exhaust unit 460 provides the depressurization to the inner space 412. The exhaust unit 460 provides the depressurization to exhaust the peripheral airflow of the substrate W to the outside of the liquid treating chamber 400. The exhaust unit 460 may include an exhaust port 461 and an exhaust device 462.

The exhaust port 461 may be connected to the first part 414a of the exhaust path forming member 414. When viewed from above, the exhaust port 461 may be disposed closer to the rotation shaft 1200 than the treating bowl 420 and the exhaust bowl 430. Also, an inlet of the exhaust port 461 may be configured to exhaust airflow introduced into the exhaust path defined by a space between the treating bowl 420 and the first part 414a of the exhaust path forming member 414. The inlet of the exhaust port 461 may be provided to face a space between the exhaust path forming member 414 and the first part 414a.

The exhaust device 462 may be a device capable of providing depressurization to the inner space 412 through the exhaust port 461. The exhaust device 462 may be a pump. However, the present invention is not limited thereto, and the exhaust device 462 may be modified into various known devices capable of providing depressurization to the inner space 412.

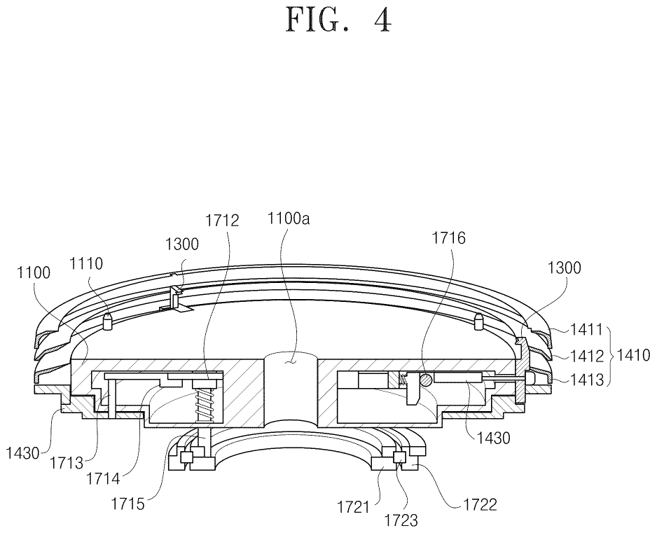

The support unit 1000 supports the substrate W in the treatment space. FIG. 4 is a diagram schematically illustrating an exemplary embodiment of the support unit of FIG. 2. Referring to FIG. 4, the support unit 1000 includes the spin chuck 1100, the rotation shaft 1200, the chuck pin 1300, a guide ring unit 1400, a chuck pin support 1600, and a driving assembly 1700.

The spin chuck 1100 supports the substrate W. The upper surface of the spin chuck 1100 is provided in a generally circular shape, and may have a diameter larger than that of the substrate W. Hereinafter, a radial direction away from a center of the spin chuck 1100 will be referred to as a fifth direction 95, and an opposite direction of the fifth direction 95 will be referred to as a sixth direction 96. A support pin 1110 configured to support a rear surface of the substrate W is provided on an upper surface of the spin chuck 1100. A plurality of support pins 1110 is provided. The support pins 1110 are arranged to have an annular ring shape as a whole by a combination thereof. The support pin 1110 is provided such that an upper end thereof protrudes from the spin chuck 1100 so that the substrate W is spaced apart from the spin chuck 1100 by a predetermined distance. A space is formed inside the spin chuck 1100. The chuck pin support 1600 to be described later may be installed inside the spin chuck 1100.

The rotation shaft 1200 is provided to be rotatable by the driver 1210. The rotation shaft 1200 is fixedly coupled to the center of the bottom surface of the spin chuck 1100. According to an example, the driver 1210 is provided below the rotation shaft 1200, and the driver 1210 provides rotational force to the rotation shaft 1200. Accordingly, the spin chuck 1100 may be rotated by the driver 1210.

The chuck pin 1300 is provided on a side surface of the spin chuck 1100. A plurality of chuck pins 1300 is provided. The chuck pin 1300 is disposed along the circumferential direction of the spin chuck 1100. A groove is formed in an upper portion of the chuck pin 1300. The groove is formed to face the substrate W. Also, the groove is formed at a height corresponding to the substrate W supported by the spin chuck 1000. When the chuck pin 1300 is moved from a separation position D1 to a support position D2, the side surface of the substrate W supported by the support pin 1110 is positioned in the groove, and the chuck pin 1300 supports the side surface of the substrate W at the side portion of the substrate W.

The chuck pin 1300 is installed in the chuck pin support 1600 installed inside the spin chuck 1100. The chuck pin 1300 may be moved together with the chuck pin support 1600. The chuck pin 1300 is provided to be movable between the separation position D1 and the support position D2. When the chuck pin 1300 moves to the separation position D1, the chuck pin 1300 moves in a direction spaced apart from the substrate W. Alternatively, the chuck pin 1300 moves in the fifth direction 95. Accordingly, the substrate W and the chuck pin 1300 are spaced apart from each other. When the chuck pin 1300 is moved to the separation position D1 while supporting the substrate W, the substrate W is handed over to the support pin 1110 and supported by the support pin 1110. The chuck pin 1300 is moved toward the substrate W when moved to the support position D2. Alternatively, the chuck pin 1300 moves in the fifth direction 96. The substrate W is handed over from the support pin 1110 to the chuck pin 1300 while the chuck pin 1300 is moved to the support position D2. Then, the chuck pin 1300 grips the side surface of the substrate W. Accordingly, the substrate W is supported by the chuck pin 1300. For example, an interval between the separation position D1 and the support position D2 may be provided as 5 mm. Details on the driving of the chuck pin 1300 by the chuck pin support 1600 will be described later.

The guide ring unit 1400 may include a guide ring 1410 and a support body 1430.

The guide ring 1410 guides the treatment liquid scattered from the substrate W to the treating bowl 420. The guide ring 1410 may be provided between the spin chuck 1100 and the treating bowl 420. The guide ring 1410 may be provided adjacent to the spin chuck 1100. The guide ring 1410 may be provided to surround the spin chuck 1100. The guide ring 1410 may be provided to be inclined downward in a direction away from the spin chuck 1100. In addition, the guide ring 1410 may be provided to be inclined downward in two stages.

The guide ring 1410 includes an upper ring 1411, an intermediate ring 1412, a lower ring 1413, and a fixed rod 1415. The upper ring 1411, the intermediate ring 1412, and the lower ring 1413 are provided to be stacked each other. Also, the upper ring 1411, the intermediate ring 1412, and the lower ring 1413 are provided to overlap at least partially when viewed from above. The upper ring 1411 is located above the intermediate ring 1412. The intermediate ring 1412 is located between the upper ring 1411 and the lower ring 1413. The lower ring 1413 is located at a position facing the upper ring 1411 in the vertical direction. The lower ring 1413, the intermediate ring 1412, and the upper ring 1411 are located in the order of the lower ring 1413, the intermediate ring 1412, and the upper ring 1411 along the third direction 93. The intervals between the upper ring 1411, the intermediate ring 1412, and the lower ring 1413 may be provided identically or may be provided differently. The intervals between the upper ring 1411, the intermediate ring 1412, and the lower ring 1413 may be determined according to the size, shape, and interval of the bowl located adjacent to the upper ring 1411, the intermediate ring 1412, and the lower ring 1413. The upper ring 1411, the intermediate ring 1412, and the lower ring 1413 are coupled to the fixed rod 1415. The fixed rod 1415 may be provided to penetrate the edge regions of the upper ring 1411, the intermediate ring 1412, and the lower ring 1430 in the third direction 93. The upper ring 1411, the intermediate ring 1412, and the lower ring 1413 may have a ring plate-shaped portion and a bulk-shaped portion provided at the outside thereof, and the fixed rod 1415 may be provided to be inserted into the bulk-shaped portion.

A groove 1410a may be formed on an inner side of the guide ring 1410. The groove 1410a may be formed at a position corresponding to the chuck pin 1300. The groove 1410a is provided to have a size in which the chuck pin 1300 may be located. Further, the groove 1410a is provided to have a depth at which the chuck pin 1300 is movable between the separation position D1 and the support position D2 within the groove 1410a. According to an example, an interval between the separation position D1 and the support position D2 is provided to be 5 mm, and the depth of the groove 1410a may be provided to be greater than 5 mm. Accordingly, the chuck pin 1300 may be located within the groove 1410a and moved. When the guide ring 1410 is disposed adjacent to the substrate W, interference may occur with the chuck pin 1300 supporting the substrate W on the side surface of the substrate W. However, when the groove 1410a is formed in the guide ring 1410, the chuck pin 1300 is located in the groove 1410a, so that interference between the guide ring 1410 and the chuck pin 1300 may be avoided. Further, since the guide ring 1410 may be disposed closer to the substrate W, the treatment liquid scattered from the substrate W may be more effectively recovered.

The support body 1430 is provided to surround the lower portion of the spin chuck 1100. The support body 1430 is provided in a continuous shape. The support body 1430 is provided in a cylindrical shape with open upper and lower portions. The support body 1430 is located under the guide ring 1410. The guide ring 1410 is installed above the support body 1430. The guide ring 1410 is coupled to the support body 1430 to have continuous coupling points. Accordingly, even when the spin chuck 1100 rotates, stress applied to the coupling point may be dispersed, and deformation and vibration of the guide ring 1410 due to excessive stress may be suppressed.

Further, the inner surface of the support body 1430 is provided to have a shape corresponding to the outer surface of the spin chuck 1100. Furthermore, an inner surface 1430a of the support body 1430 is provided to be adjacent to an outer surface 1100a of the spin chuck 1100. According to an example, the inner surface 1430a of the support body 1430 and the outer surface 1100a of the spin chuck 1100 may be formed to be stepped, and the respective stepped surfaces may be provided to be adjacent to each other. Accordingly, the space occupied by the support body 1430 may be minimized.

A discharge port 1431 is formed in the support body 1430. When the treatment liquid is not guided to the cup body 420 through the guide ring 1410 and is scattered to the support body 1430, the treatment liquid is discharged to the outside of the support body 1430 through the discharge port 1431. The discharge port 1431 may be provided in a slot shape. A longitudinal direction of the discharge port 1431 may be provided to be the same as the circumferential direction of the support body 1430. A plurality of discharge ports 1431 may be provided. The discharge port 1431 may be formed along the circumferential direction of the support body 1430.

When the guide ring unit 1400 is provided to be adjacent to the substrate W supported by the spin chuck 1100, interference between the support body 1430 and the lower portion of the chuck pin 1300 may occur. An insertion port 1432 may be formed in the support body 1430 to minimize interference between the chuck pin 1300 and the support body 1430.

The insertion port 1432 may be formed such that a lower portion of the chuck pin 1300 is inserted. A plurality of insertion ports 1432 may be provided. The insertion ports 1432 may be provided in a number corresponding to the number of chuck pins 1300. The insertion port 1432 may be formed along the circumferential direction of the support body 1430. The insertion port 1432 may be formed at a position corresponding to the chuck pin 1300.

Interference between the chuck pin 1300 and the guide ring unit 1400 may be minimized by the groove 1401 and the insertion port 1432, and the guide ring 1410 may be installed to be closer to the substrate W. Accordingly, the guide ring 1410 may guide the treatment liquid scattered from the substrate W to be efficiently directed toward the treating bowl 420.

A chuck pin support 1610 supports the chuck pin 1300. The chuck pin support 1600 is installed inside the spin chuck 1100. The chuck pin support 1610 has a radial direction of the spin chuck 1300 as a longitudinal direction. The chuck pin support 1610 is provided to reciprocate in the fifth direction 95 and the sixth direction 96. According to an example, a guide member (not illustrated) may be provided on the spin chuck 1300, and the chuck pin support 1300 may be installed on the guide member. Furthermore, the chuck pin support 1610 has a support rod 1611 and the support rod 1611 is provided to penetrate the sidewall of the spin chuck 1300 and protrude outward. The chuck pin 1300 is fixedly coupled to the support rod 1611. Accordingly, the chuck pin 1300 is moved together when the chuck pin support 1610 is moved. Furthermore, the chuck pin support 1610 has a protrusion 1613. The protrusion 1613 has a shape protruding downward from the chuck pin support 1610. The protrusion 1613 has a perpendicular surface 1613a and an inclined surface 1613a. The perpendicular surface 1613a and the inclined surface 1613a are combined with each other to form a continuous surface. The perpendicular surface 1613a is formed to extend in the vertical direction from a lower surface of the chuck pin support 1610. The perpendicular surface 1613a may have a quadrangular shape. The inclined surface 1613b is formed to extend from a lower end of the perpendicular surface 1613a. The inclined surface 1613b is provided to have an inclination with respect to the vertical direction. The inclination is formed so that a width of the inclined surface 1613b decreases as it goes down to a lower portion of the protrusion in the cross section in the longitudinal direction of the chuck pin support 1610.

A first elastic member 1650 is installed at one side of the chuck pin support 1610. A fixed structure 1120 fixed to the spin chuck 1100 is formed inside the spin chuck 1100, and one end of the first elastic member 1650 is coupled to the fixed structure 1120. Further, the other end of the first elastic member 1650 is coupled to the chuck pin support 1610. The first elastic member 1650 is installed to push the chuck pin support 1610 in the fifth direction 95. The first elastic member 1650 is provided to be compressed while the chuck pin 1300 moves to the support position D2 when the pusher 1716 ascends. The first elastic member 1650 is provided to apply elastic force in the fifth direction 95 when the chuck pin 1300 is positioned at the support position D2. Accordingly, when the pusher 1716 descends, the chuck pin 1300 is moved in the fifth direction 95 by elastic force, and the chuck pin 1300 is moved from the support position D2 to the separation position D1. According to an example, the first elastic member 1650 may be a spring.

The driving assembly 1700 is provided to simultaneously move the guide ring unit 1400 and the chuck pin 1300. The chuck pin 1300 may be moved together when the guide ring 1400 is moved. When the chuck pin 1300 is moved to the support position D2, the guide ring unit 1400 may be moved to a raised position H2. Also, when the chuck pin 1300 is moved to the separation position D1, the guide ring unit 1400 may be moved to a lowered position H1. The raised position H2 is a position where the guide ring unit 1400 is raised and is located higher than the upper surface of the spin chuck 1100. The lowered position H1 is a position where the guide ring 1400 is lowered and is located lower than the upper surface of the spin chuck 1100.

The driving assembly 1700 includes a first driving unit 1710 and a second driving unit 1730. The first driving unit 1710 may serve as a structure for simultaneously moving the chuck pin 1300 and the guide ring unit 1400, and the second driving unit 1730 may be configured to provide power to the first driving unit 1710.

The first driving unit 1710 includes a connector 1711, a pusher 1716, and a bearing 1720.

The connector 1711 is provided inside the spin chuck 1100. The connector 1711 has a ring structure 1712, a fixed rod 1713, a spoke 1714, and a connection rod 1715.

The ring structure 1712 is provided in a shape surrounding the through hole 1100a. The connection rod 1715 is installed under the ring structure 1712. The connection rod 1715 has a shape that protrudes and extends from the ring structure 1711 in the down direction. The connection rod 1715 is provided to penetrate the lower wall of the spin chuck 1100 and protrude from the spin chuck 1100. The bearing 1720 to be described later is coupled to a lower end of the connection rod 1714. Also, the connection rod 1715 may be provided to be inserted into a second elastic member 1740.

The spoke 1714 has a shape radiating from the ring structure 1712. A plurality of spokes 1714 may be provided. The plurality of spokes 1714 include a plurality of first spokes 1714a and a plurality of second spokes 1714b. The first spoke 1714a and the second spoke 1713b are provided so as to have a predetermined interval. The first spoke 1714a and the second spoke 1713b are provided to be spaced apart from each other. The length of the second spoke 1713b may be shorter than the length of the first spoke 1714a.

The fixed rod 1713 is installed on the first spoke 1714a. The fixed rod 1713 has a shape extending in the vertical direction from the distal end of the first spoke 1714a. The fixed rod 1713 is provided to penetrate the lower wall of the spin chuck 1100. The support body 1430 is coupled to the lower end of the fixed rod 1713. Accordingly, when the connector 1711 is moved, the guide ring 1410 and the support body 1430 may be moved together.

The pusher 1716 is coupled to the second spoke 1714b. The pusher 1716 may be coupled to have a shape extending from the distal end of the second spoke 1714b to the side surface of the second spoke 1714b. The pusher 1716 may be provided at a position partially overlapping the protrusion 1613 when viewed from above. Further, the pusher 1716 is provided so as to partially overlap the inclined surface 1613b when viewed from above. A surface of the pusher 1716 corresponding to the inclined surface 1613b may have a curved surface. According to an example, a vertical cross section of the pusher 1716 may be a circle. The pusher 1716 is provided to ascend to a position at which the pusher 1716 is in contact with the perpendicular surface 1613a and descend to a position at which the pusher 1716 is spaced apart from the protrusion 1613.

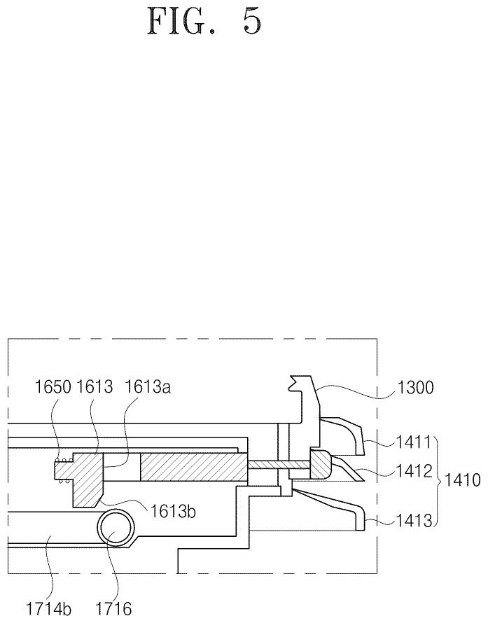

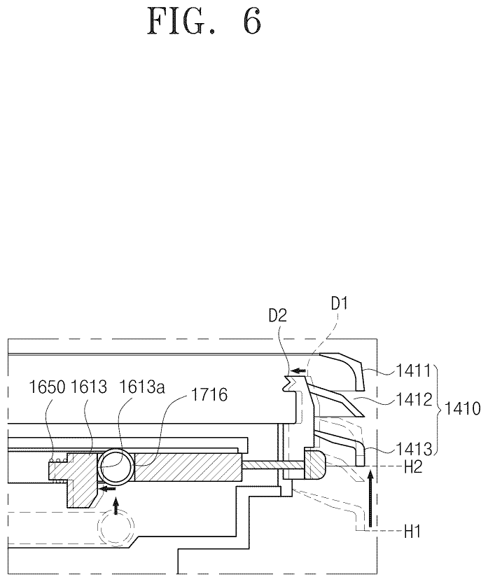

FIGS. 5 and 6 are diagrams illustrating a process in which the chuck pin and the guide ring are simultaneously moved. Referring to FIGS. 5 and 6, when the pusher 1716 ascends, the pusher 1716 makes contact with the inclined surface 1613b and the vertical perpendicular 1613a in order of the inclined surface 1613b and the perpendicular surface 1613a. When the pusher 1716 ascends, the pusher 1630 applies force in the third direction 93 with respect to the inclined surface 1613b while being in contact with the inclined surface 1613b. Since the direction of the force is not provided perpendicular to the direction of inclination of the inclined surface 1613b, the force by the pusher 1716 is not offset, and the force in the sixth direction 96 pushes the inclined surface 1613b. Accordingly, the chuck pin support 1610 is moved in the sixth direction 96. The pusher 1716 ascends to the height at which the perpendicular surface 1613a is located. Simultaneously, the chuck pin 1300 is moved to the support position D2, and the chuck pin 1300 grips the substrate W. For example, an interval between the separation position D1 and the support position D2 may be provided as 5 mm. Also, when the pusher 1716 ascends, the guide ring unit 1400 ascends together. The guide ring unit 1400 is moved from the lowered position H1 to the raised position H2. According to an example, an interval between the lowered position H1 and the raised position H2 may be provided as 20 mm. Hereinafter, when the chuck pin 1300 is positioned at the separation position D1 and the guide ring unit 1400 is positioned at the lowered position H1, the support unit 1000 is in the open state, and when the chuck pin 1300 is positioned at the support position D2 and the guide ring unit 1400 is positioned at the raised position H2, the support unit 100 is in the closed state.

The connection rod 1715 may be provided to be inserted into the second elastic member 1740. The second elastic member 1740 is provided to raise the connector 1711. According to an example, when the connector 1711 is lowered, the second elastic member 1740 is compressed. One end of the second elastic member 1740 is provided to be coupled to the lower wall of the spin chuck 1100, and the other end thereof is provided to be coupled to the ring structure 1712. Therefore, the second elastic member may apply elastic force in a direction in which the connector 1711 is raised.

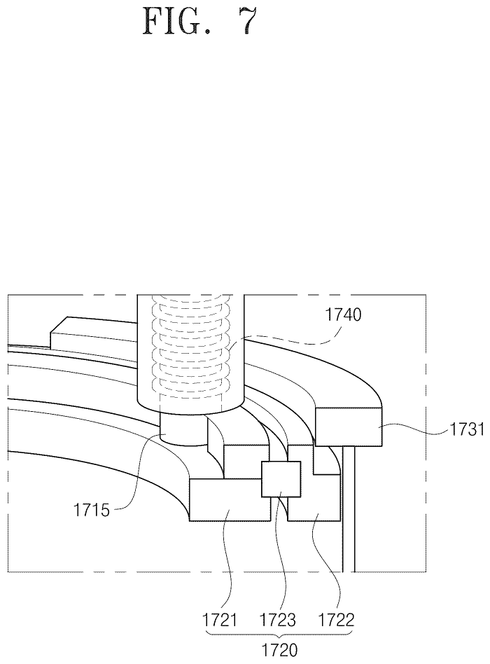

The bearing 1720 is provided to rotate the substrate W even when the guide ring unit 1400 is located at the lowered position H1. FIG. 7 is a diagram illustrating the bearing of FIG. 4 in detail. Referring to FIG. 7, the bearing 1720 may include an inner ring 1721, an outer ring 1722, and a roller 1723. The inner ring 1721 is provided in a ring shape, and is provided to surround the rotation shaft 1200. Also, the inner ring 1721 is coupled to the connection rod 1715. Accordingly, the inner ring 1721 is rotated together when the spin chuck 1100 is rotated. The outer ring 1722 is provided in a ring shape, and is provided to surround the inner ring 1721. The upper surface 1722a of the outer ring is provided as a horizontal plane. The upper surface 1722a of the outer ring may be provided in a stepped shape. According to an example, the upper surface 1722a of the outer ring is provided in a stepped shape, the upper surface of each operation is provided as a horizontal plane, and the upper surface located at the outer side may be provided in a shape formed at a higher position than the upper surface located at the inner side. The handle 1731 is in contact with the upper surface 1722a of the outer ring. Since the upper surface 1722a is provided in the horizontal plane, force applied from the handle 1731 may be stably transferred to the bearing 1720. A roller 1723 is provided between the inner ring 1721 and the outer ring 1722. The inner ring 1721 is provided to be independently rotatable with respect to the outer ring 1722 by the roller 1723. According to an example, the bearing 1720 may be a cross roller bearing.

The second driving unit 1730 includes a handle 1731 and a driver 1733. When viewed from above, the handle 1731 may partially overlap the outer ring 1722 of the bearing 1720. The driver 1730 drives the handle 1731 to move up and down. According to an example, the driver 1730 may be a cylinder or an actuator. The handle 1731 is brought into contact with the upper surface 1722a of the outer ring while descending. The handle 1731 pulls the bearing 1720 down while further descending. As the bearing 1720 descends, the guide ring unit 1400 connected to the bearing 1720 descends together. The guide ring unit 1400 descends to the lowered position H1. At the same time, the chuck pin 1300 is moved up to the separation position D1. When the spin chuck 1100 is rotated in a state in which the handle 1731 and the bearing 1720 are in contact with each other, the outer ring 1722 is fixed by the handle 1731, but the inner ring 1711 may be rotated because the inner ring 1711 and the outer ring 1722 are provided to be rotated independently of each other.

Hereinafter, a method of treating a substrate will be described. The substrate treating method described below may be performed by the substrate treating apparatus described with reference to FIGS. 1 to 7. Accordingly, hereinafter, a substrate treating method according to an exemplary embodiment will be described by referring to reference numerals illustrated in FIGS. 1 to 7. In addition, the substrate treating method described below may be performed by controlling, by the controller, the configurations included in the substrate treating apparatus described above.

The controller 600 may control the entire operation of the substrate treating apparatus 1000. The controller (not illustrated) may include a Central Processing Unit (CPU), a Read Only Memory (ROM), and a Random Access 44-16 Memory (RAM). The CPU executes desired treatment, such as etching treatment, according to various recipes stored in their storage area. In the recipe, device control information for process conditions is input. Meanwhile, these programs or recipes indicating processing conditions may be stored in a non-transitory computer-readable medium. The non-transitory computer-readable medium refers to a medium that stores data semi-permanently and is readable by a computer, rather than a medium that stores data for a short moment, such as a register, cache, and memory. Specifically, the above-described various applications or programs may be stored and provided on a non-transitory readable medium, such as a CD, DVD, hard disk, Blu-ray disk, USB, memory card, or ROM.

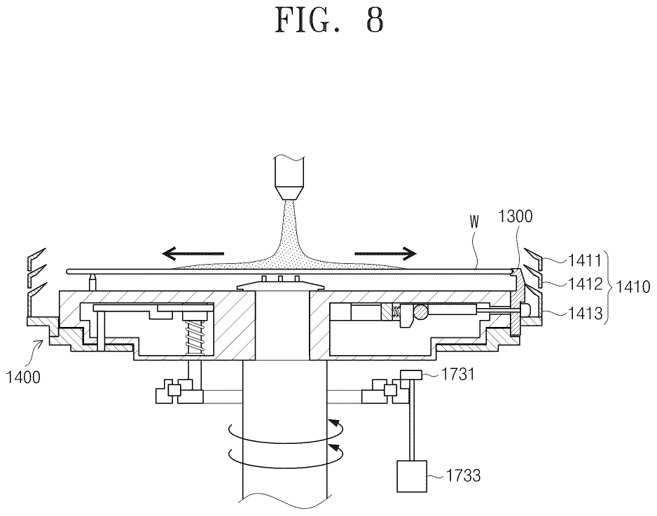

FIG. 8 is a flowchart illustrating a substrate treating method according to an exemplary embodiment of the present invention. Referring to FIG. 8, the substrate treating method includes a loading operation S100, a gripping operation S200, a first rotating operation S300, a second rotating operation S400, a rinsing operation S500, and a drying operation S600.

The loading operation S100 is an operation of loading the substrate W onto the spin chuck 1100. In the loading operation S100, the transfer robot 320 loads the substrate W into the liquid treating chamber 400. In the loading operation S100, the support unit 1100 is in the open state. In the open state, the handle 1731 is lowered so that the chuck pin 1300 is located at the separation position D1, and the guide ring unit 1400 is located at the lowered position H1. The first elastic member 1650 pushes the chuck pin support 1610, and the second elastic member 1740 is compressed. Since the guide ring unit 1400 is located at the lowered position H1, interference between the guide ring unit 1400 and the transfer robot 320 and the substrate W entering the spin chuck 1100 may be avoided. The transfer robot 320 loads the substrate W onto the support pin 1110 after entering the liquid treating chamber 400. Thereafter, the transfer robot 320 retreats from the liquid treating chamber 400.

After the loading operation S100, the gripping operation S200 is performed. The gripping operation S200 is an operation in which the chuck pin 1300 grips the substrate W placed on the support pin 1110. In the gripping operation S200, the support unit 1100 is in the closed state. In the gripping operation S200, the handle 1731 ascends. The second elastic member 1740 pushes the connector 1711 upward, and the pusher 1716 ascends together. While the pusher 1716 ascends, the protrusion 1613 of the chuck pin support is pushed in the sixth direction 96, the chuck pin support 1600 is moved in the sixth direction 96, and the chuck pin 1300 is moved to the support position D2. At the same time, the guide ring unit 1400 connected to the connector 17110 is also moved to the raised position H2. The chuck pin 1300 grips the side surface of the substrate W while moving to the support position D2. Accordingly, the substrate W is supported by the chuck pin 1300, and the center of the substrate W and the center of the spin chuck 1100 may be aligned.

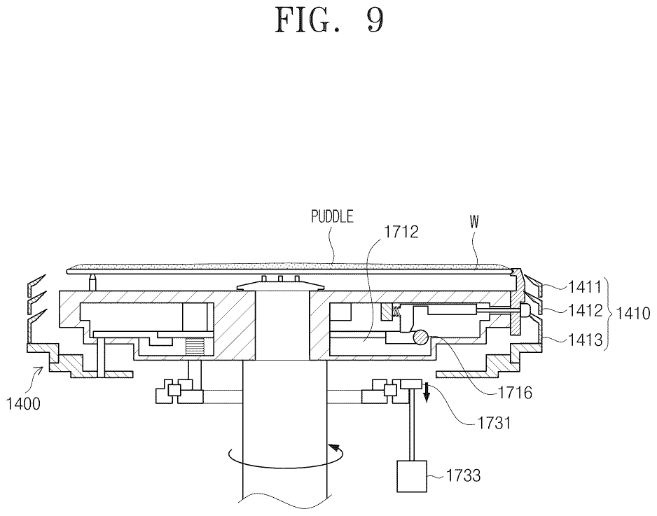

After the gripping operation S200, the first rotating operation S300 may be performed. FIG. 9 is a diagram illustrating a state in which a treatment liquid is supplied onto the substrate in the first rotating operation. Referring to FIG. 9, the first rotating operation S300 is an operation of supplying a treatment liquid onto the substrate W and applying the supplied treatment liquid by rotating the substrate W. In the first rotating operation S300, a puddle consisting of the treatment liquid may be formed. The treatment liquid may be a first treatment liquid, and according to an example, the first treatment liquid may be an etching liquid. In the first rotating operation S300, the spin chuck 1100 is rotated at a first speed.

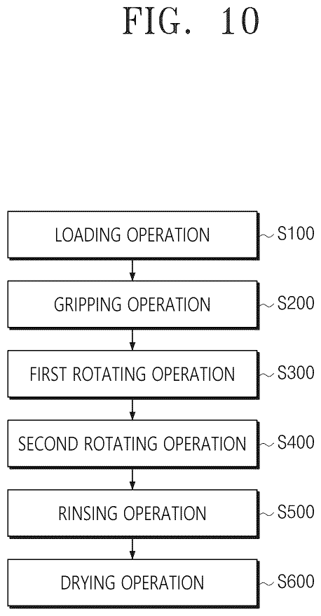

After the first rotating operation S300, the second rotating operation S400 may be performed. FIG. 10 is a diagram illustrating a state in which the treatment liquid is supplied onto the substrate in the second rotating operation. Referring to FIG. 10, in the second rotating operation S400, the support unit 1000 is converted into the open state, and the support unit 1000 is rotated at a second speed. The handle 1731 descends in the second rotating operation S400. The handle 1731 comes into contact with the bearing 1720 while descending, and applies force to the bearing 1720 in a downward direction. In addition, as the connector 1711 descends, the guide ring unit 1400 is moved to the lowered position H1. In addition, the second elastic member 1740 is compressed, and the pusher 1716 descends. The first elastic member 1650 pushes the chuck pin support 1610 in the fifth direction 95, and the chuck pin 1300 is moved to the separation position D1. Accordingly, the chuck pin 1300 and the guide ring 1410 are spaced apart from the puddle to minimize a bridge phenomenon, thereby preventing the puddle from being broken. Also, in the second rotating operation S400, the substrate W is rotated at the second speed. The second speed may be slower than the first speed. According to an example, the second speed may be 10 RPM or less. As the substrate W is rotated at the low speed, uniformity of the puddle may be improved. Here, uniformity of the puddle refers to a degree to which a height of the puddle formed on the substrate is uniform depending on a region of the substrate. Accordingly, treatment uniformity of the substrate W may be improved.

Referring back to FIG. 8, the rinsing operation S500 may be performed after the second rotating operation S400. In the rinsing operation S500, the handle 1731 ascends again, the chuck pin 1300 moves to the support position D2, and the guide ring unit 1400 moves to the raised position H2. Thereafter, the treatment liquid is supplied onto the substrate. The treatment liquid may be a second treatment liquid. The second treatment liquid may be a rinsed liquid. According to an example, the rinsing liquid may be deionized water. Also, in the rinsing operation S500, the substrate W is rotated at the third speed. The third speed may be higher than the second speed. The substrate W may be rotated at the third speed after the second treatment liquid is supplied, or may be rotated at the third speed together with the supply of the second treatment liquid. Accordingly, the first treatment liquid may be substituted with the second treatment liquid.

The drying operation S600 may be performed after the rinsing operation S500. In the drying operation S600, the spin chuck 1100 rotates at a fourth speed. The fourth speed may be faster than the third speed. Accordingly, the second treatment liquid supplied onto the substrate W may be scattered to the outside of the substrate W, and the treatment liquid remaining on the substrate W may be dried. A drying liquid may be selectively supplied in the drying operation S600. According to an example, the drying liquid may be isopropyl alcohol (IPA).

According to the exemplary embodiment of the present invention, even if the support unit 1000 includes the guide ring unit 1400, the guide ring unit 1400 may be lowered when the puddle is formed, and the chuck pin 1300 may be spaced apart from the substrate W to stably maintain the puddle.

Further, according to the exemplary embodiment of the present invention, even if the guide ring unit 1400 is lowered to the handle 1731, the spin chuck 1100 may be rotated by the bearing 1720. Accordingly, the puddle formed on the substrate W is moved to the edge region of the substrate W by centrifugal force, thereby improving uniformity of the puddle and improving uniformity of in-plane treatment of the substrate W.

In the above-described example, the present invention has been described based on the case where the substrate W is dried by rotating the substrate W or supplying the drying liquid in the drying operation S600 as an example. However, the present invention is not limited thereto, and a configuration of injecting drying gas onto the substrate W may be further added so as to dry the treatment liquid.

The specification described above provides examples of the present disclosure. Further, the description provides exemplary embodiments of the present disclosure and the present disclosure may be used in other various combinations, changes, and environments. That is, the present disclosure may be changed or modified within the scope of the present disclosure described herein, within a range equivalent to the description, and/or within the knowledge or technology in the related art. The embodiment shows an optimum state for achieving the spirit of the present disclosure and may be changed in various ways for the detailed application fields and use of the present disclosure. Therefore, the detailed description of the present disclosure is not intended to limit the present disclosure in the embodiment. Further, the claims should be construed as including other embodiments.

In the above-described exemplary embodiment, the method is described based on a flowchart as a series of operations or blocks, but the present invention is not limited to the order of operations, and some operations may occur in a different order or simultaneously with other operations as described above. In addition, those skilled in the art will understand that the operations illustrated in the flowchart are not exclusive and that other operations may be included or one or more operations in the flowchart may be deleted without affecting the scope of the present invention.

1. An apparatus for treating a substrate, the apparatus comprising:
a treating bowl configured to a treatment space for treating a substrate;
a support unit configured to support and rotate the substrate in the treatment space; and
a treatment liquid supply unit configured to supply a treatment liquid to an upper surface of the substrate supported by the support unit,
wherein the support unit includes:
a spin chuck on which the substrate is placed and rotates;
a chuck pin installed on the spin chuck to support a side portion of the substrate placed on the spin chuck;
a chuck pin support configured to support the chuck pin;
a guide ring unit provided between the treating bowl and the spin chuck and having a shape surrounding the spin chuck in a circumferential direction of the spin chuck; and
a driving assembly configured to move the guide ring unit so that the guide ring unit is moved between a raised position and a lowered position,
the raised position is a position where the guide ring unit ascends to guide a treatment liquid scattered from the substrate supported by the support unit to the treating bowl,
the lowered position is the position where the guide ring unit is lowered below the support unit,
when the guide ring unit moves to the raised position, the chuck pin is moved to a support position to support the substrate by gripping the side portion of the substrate supported by the spin chuck, and when the guide ring unit moves to the lowered position, the chuck pin is moved to a separation position, which is a position spaced apart from the substrate supported by the spin chuck, and
the driving assembly is provided to rotate the spin chuck in a state where the guide ring unit is moved to the lowered position.

2. The apparatus of claim 1, wherein the driving assembly includes:
a first driving unit to which the guide ring unit is coupled; and
a second driving unit configured to move the first driving unit in a vertical direction,
the first driving unit includes a bearing, and
the second driving unit includes a handle provided to be in contact with the bearing.

3. The apparatus of claim 2, wherein the bearing includes:
an outer ring and an inner ring; and
a roller provided between the outer ring and the inner ring, and
the handle is provided to be in contact with the outer ring.

4. The apparatus of claim 3, wherein an upper surface of the outer ring is provided as a horizontal plane,
the handle is provided to at least partially overlap the outer ring when viewed from above, and
a bottom surface of the handle is provided to be in contact with the horizontal surface.

5. The apparatus of claim 3, wherein the outer ring is provided to be fixed against a rotation of the inner ring when the inner ring rotates in a state where the handle is in contact with the outer ring.

6. The apparatus of claim 3, wherein the bearing is a cross roller bearing.

7. The apparatus of claim 3, wherein the chuck pin support includes a protrusion that has a longitudinal direction in a radial direction of the spin chuck and extends downward from the chuck pin support,
the first driving unit further includes a connector connecting the guide ring unit and the bearing,
the connector has a pusher at a position partially overlapping the protrusion when viewed from above,
when the guide ring unit is moved to the raised position, the pusher pushes the protrusion to move the chuck pin to the support position, and
when the guide ring unit is moved to the lowered position, the chuck pin is moved to the separation position.

8. The apparatus of claim 3, wherein the separation position is a position where the treatment liquid supplied onto the substrate supported by the chuck pin does not contact the chuck pin.

9. The apparatus of claim 3, wherein the guide ring unit includes:
a guide ring that is provided in a ring shape and has a groove at a position corresponding to the chuck pin; and
a support body configured to support the guide ring,
the guide ring is provided to be adjacent to the substrate supported by the chuck pin at the raised position, and the chuck pin is located in the groove, and
the groove has a width that does not interfere with the guide ring when the chuck pin is moved between the separation position and the support position.

10-14. (canceled)

15. An apparatus for treating a substrate, the apparatus comprising:
a treating bowl configured to a treatment space for treating a substrate;
a support unit configured to support and rotate the substrate in the treatment space; and
a treatment liquid supply unit configured to supply a treatment liquid to an upper surface of the substrate supported by the support unit,
wherein the support unit includes:
a spin chuck on which the substrate is placed and rotates;
a chuck pin installed on the spin chuck to support a side portion of the substrate placed on the spin chuck;
a guide ring unit provided between the treating bowl and the spin chuck and having a shape surrounding the spin chuck in a circumferential direction of the spin chuck; and
a driving assembly configured to move the guide ring so that the guide ring unit is moved between a raised position and a lowered position,
the raised position is a position where the guide ring unit ascends to guide a treatment liquid scattered from the substrate supported by the support unit to the treating bowl,
the lowered position is the position where the guide ring unit is lowered below the support unit,
when the guide ring unit moves to the raised position, the chuck pin is moved to a support position to support the substrate by gripping the side portion of the substrate supported by the spin chuck, and when the guide ring unit moves to the lowered position, the chuck pin is moved to a separation position, which is a position spaced apart from the substrate supported by the spin chuck, and
the driving assembly includes:
a first driving unit to which the guide ring unit is coupled; and
a second driving unit configured to move the first driving unit in a vertical direction,
the first driving unit includes a bearing, and
the second driving unit includes a handle provided to be in contact with the bearing,
the driving assembly is provided to rotate the spin chuck in a state where the guide ring unit is moved to the lowered position,
the bearing includes:
an outer ring and an inner ring; and
a roller provided between the outer ring and the inner ring, and
the handle is provided to be in contact with the outer ring, and
the outer ring is provided to be fixed against a rotation of the inner ring when the inner ring rotates in a state where the handle is in contact with the outer ring.

16. The apparatus of claim 15, wherein the separation position is a position where the treatment liquid supplied onto the substrate supported by the chuck pin does not contact the chuck pin.

17. The apparatus of claim 16, wherein the guide ring unit includes:
a guide ring that is provided in a ring shape and has a groove at a position corresponding to the chuck pin; and
a support body configured to support the guide ring,
the guide ring is provided to be adjacent to the substrate supported by the chuck pin at the raised position, and the chuck pin is located in the groove, and
the groove has a width that does not interfere with the guide ring when the chuck pin is moved between the separation position and the support position.

18. The apparatus of claim 17, wherein the support unit includes a chuck pin support to support the chuck pin,
the chuck pin support includes a protrusion that has a longitudinal direction in a radial direction of the spin chuck and extends downward from the chuck pin support,
the chuck pin is installed on the chuck pin support,
the first driving unit further includes a connector connecting the guide ring unit and the bearing,
the connector has a pusher at a position partially overlapping the protrusion when viewed from above,
when the guide ring unit is moved to the raised position, the pusher pushes the protrusion to move the chuck pin to the support position, and
when the guiding unit is moved to the lowered position, the chuck pin is moved to the separation position.

19. The apparatus of claim 18, further comprising:
a controller,
the controller controls to perform a second rotating operation of rotating the spin chuck at a second speed in an open state, and
the open state is a state where the substrate is placed on the spin chuck, the chuck pin is moved to a separation position, and the guide ring unit is moved to a lowered position.

20. The apparatus of claim 19, wherein the controller controls to perform the second rotating operation after:
a loading operation of loading the substrate onto the spin chuck in the open state;
a gripping operation of switching from the open state to a closed state; and
a first rotating operation of supplying the treatment liquid onto the substrate in the closed state and rotating the spin chuck at a first speed, and
the second speed is lower than the first speed.
